(19) United States
(12) Patent Application Publication
(10) Pub. No.: US 2010/0238641 A1
(43) Pub. Date: Sep. 23, 2010

(54) SHIELD STRUCTURE OF A TUNER APPARATUS

(76) Inventors: Tatsuo Saito, Miyagi-Ken (JP); Shigetomo Chiba, Miyagi-Ken (JP); Yasuharu Kudo, Miyagi-Ken (JP)

Correspondence Address: BRINKS HOFER GILSON & LIONE, P.O. BOX 10395, CHICAGO, IL, 60610, US

(21) Appl. No.: 12/727,012

(22) Filed: Mar. 18, 2010

(30) Foreign Application Priority Data
Mar. 19, 2009 (JP) 2009-068494

(51) Int. Cl. H05K 9/00

(52) U.S. Cl. 361/816

(57) ABSTRACT

A shield structure of a tuner apparatus includes: a circuit board on which a tuner circuit is provided; a shield case of sheet metal which accommodates and holds the circuit board; and a RF connector which is fixed to one side plate of the shield case so as to protrude outward and is electrically connected to the tuner circuit, wherein a box-shaped outer case is formed by connecting a case member of sheet metal which covers the shield case with the exception of the bottom surface portion thereof and the one side plate and a plate member of sheet metal which has a through hole, through which the RF connector passes, and covers the one side plate of the shield case, and wherein the outer case is unitized with the shield case.

### CROSS REFERENCE TO RELATED APPLICATION

The present invention claims priority to and contains subject matter related to Japanese Patent Application JP 2009-068494 filed in the Japanese Patent Office on Mar. 19, 2009, the entire contents of which is incorporated herein by reference.

### BACKGROUND

1. Technical Field

The present disclosure relates to a shield structure of a tuner apparatus in which a RF connector is provided in a protruding manner at one side plate of a shield case which accommodates a circuit board, and more particularly, to a shield structure of a tuner apparatus in which it is necessary to electromagnetically and strictly shield a tuner circuit provided on the circuit board.

2. Related Art

In a unitized tuner apparatus, a circuit board equipped with a tuner which receives a high frequency signal reduces diving or jumping of the electromagnetic noise by being accommodated into a shield case of sheet metal. Further, by providing a RF connector to one side plate of the shield case to protrude sideways, the tuner apparatus can be considerably reduced in thickness. The shield case used in this kind of tuner apparatus is generally composed of a frame body (shield frame), which is assembled in a rectangular shape or the like, a partitioning plate (shield plate), which partitions an inner space of the frame body, and upper and lower covers, which close an upper opening and a lower opening of the frame body, respectively. The frame body and the partitioning plate are often formed by bending one sheet of metal plate, and the RF connector is fixed to one side plate of the frame body by caulking or the like so as to protrude outward. The circuit board is held to the frame body and the partitioning plate while making a group of terminals protrude downward, and a grounding pattern provided on the circuit board is conducted to the frame body and the partitioning plate (for example, refer to Japanese Unexamined Patent Application Publication No. 10-163668). Then, by fixing a plurality of attaching legs, which are vertically suspended from a bottom end of the frame body, to an outer circuit on a motherboard side and by connecting a group of terminals to the outside circuit on the motherboard side, this kind of tuner apparatus is mounted on the motherboard and a coaxial cable or the like is connected to the RF connector. As a result, a receiving signal is supplied via the RF connector to the tuner circuit or the like of the circuit board, and the signal which is processed by the tuner circuit or the like is adapted to be supplied to the outer circuit on the motherboard side.

However, since the frame body of the shield case of the tuner apparatus has notches or holes to hold the circuit board at multiple positions, the occurrence of diving or jumping of electronic noise via the notches or holes is inevitable. For this reason, in a case in which another high frequency unit is mounted near to the tuner apparatus on a motherboard, it is desirable to reliably prevent the diving or jumping of the electromagnetic noise by shielding the tuner apparatus more strictly than usual. In order to respond to such a request, consideration has been given to completely covering the shield case of the tuner apparatus provided on the motherboard with another shield case (outer case). However, since the outer case which is applicable to a tuner apparatus having a RF connector at one side plate of the shield case in a protruding manner needs a through-hole through which the RF connector is inserted, the outer case made by forming a metal plate into a box shape can not be put over the shield case. Finally, it is considered that combining a plurality of members (for example, two members) which partly cover the shield case into a box-shaped outer case is a realistic approach. However, if the outer case is configured as a combination of plural members, since an operation to connect these plural members to each other or an operation to attach the plural members to the shield case tends to be cumbersome, there occurs a problem that cost of the tuner apparatus becomes high due to the addition of the outer case.

### SUMMARY

According to a first aspect, a shield structure of a tuner apparatus, includes: a circuit board on which a tuner circuit is provided; a shield case of sheet metal, which accommodates and holds the circuit board; and a RF connector, which is fixed to one side plate of the shield case so as to protrude outward and is electrically connected to the tuner circuit, wherein a box-shaped outer case includes a case member of sheet metal, which covers the shield case with the exception of the bottom surface portion thereof connected with the one side plate and a plate member of sheet metal, which has a through hole, through which the RF connector passes, and covers the one side plate of the shield case, and wherein the outer case is unitized with the shield case.

The outer case of sheet metal which has a connection between the case member and the plate member superimposes the plate member having a through hole through which the RF connector is inserted on the one side plate of the shield case so that it can be easily attached thereto, and the case member which is fitted over the shield case from a side opposite to the plate member is easily connected to the plate member so that a box-shaped outer case can be formed.

### BRIEF DESCRIPTION OF THE DRAWINGS

FIG. 1 is an appearance view of a tuner apparatus according to an embodiment of the invention seen obliquely from above.

FIG. 2 is an exploded perspective view corresponding to FIG. 1 of the tuner apparatus.

FIG. 3 is an appearance view of the tuner apparatus seen obliquely from below.

FIG. 4 is an exploded perspective view corresponding to FIG. 3 of the tuner apparatus.

FIG. 5 is an appearance view of the tuner apparatus seen at an angle different from that in FIG. 1.

FIG. 6 is an explanatory view showing an attaching structure of an outer case in “A” portion of FIG. 5.

FIG. 7 is an explanatory view showing a state in which a tuner apparatus according to another embodiment of the invention is attached to a motherboard.

### DESCRIPTION OF EXEMPLARY EMBODIMENTS

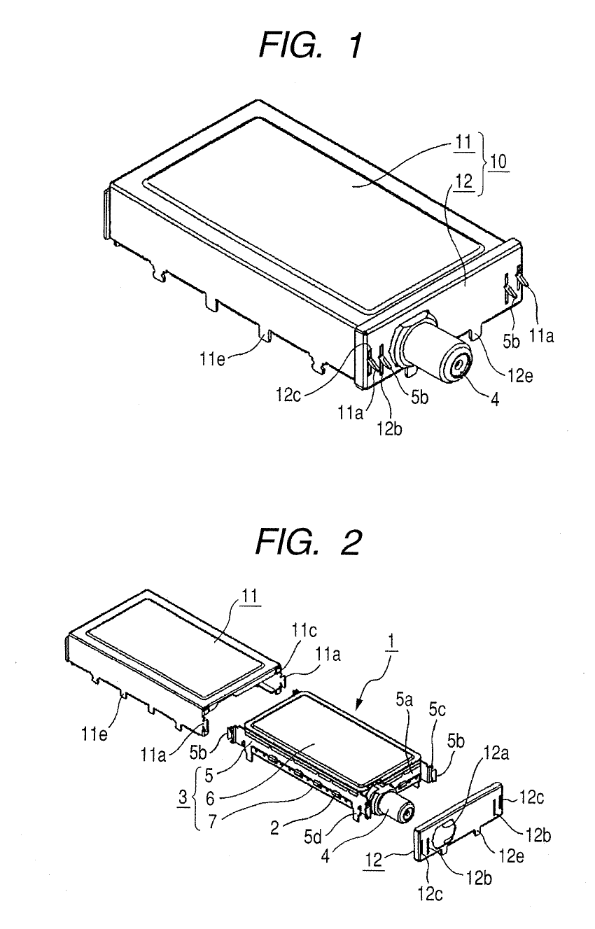

Next, an embodiment of the invention will be described with reference to FIGS. 1 to 6. The tuner apparatus shown in these drawings is composed of a tuner unit 1 which accommodates and holds a circuit board 2 with a tuner circuit into a shield case 3 to be unitized therewith and an outer case 10 of sheet metal which covers the shield case 3 of sheet metal, and a RF connector 4 is provided to the tuner unit 1 to protrude sideways. In addition, the outer case 10 is formed in a box shape by connecting a case member 11 and a plate member 12.

First, configuration of the tuner unit 1 will be described. The shield case 3 is composed of a frame body (shield frame) 5 assembled in a rectangular shape, a partitioning plate (shield plate) (not shown) which partitions an inner space of the frame body 5, an upper cover 6 which closes an upper opening of the frame body 5, and a lower cover 7 which closes a lower opening of the frame body 5, wherein the frame body 5 and the partitioning plate are formed by bending one sheet of metal plate. A plurality of attaching legs 5d are vertically suspended from a bottom end of the frame body 5, and the frame body 5 is mounted to a motherboard by fixing the attaching legs 5d to the motherboard (not shown). In addition, the RF connector 4 is caulk-fixed and solder-bonded to one side plate 5a of the frame body 5. The frame body 5 includes attaching pieces 5b which are respectively provided at one end side (RF connector 4 side) and the other end side in a longitudinal direction of a side plate extending longitudinally adjacent to one side plate 5a, and protruding pieces 5c for regulation (refer to FIG. 6) which are formed near to a top edge and a bottom edge of a base end portion of each of the attaching pieces 5b. Further, a coaxial cable or the like is connected to the RF connector 4 so that a receiving signal is supplied to the tuner circuit or the like of the circuit board 2 via the RF connector 4.

The circuit board 2 is held in the frame body 5 and the partitioning plate, and a grounding pattern provided on the circuit board 2 is rendered conductive with the frame body 5 and the partitioning plate. Further, a group of terminals 8 derived from the circuit board 2 protrude downward, and the group of terminals 8 are adapted to be connected to an outer circuit on the motherboard side.

The outer case 10 is assembled in a box shape at a step in which it is attached to the shield case 3. That is, this outer case 10 is formed by connecting the case member 11 of sheet metal which covers the shield case 3 with the exception of the lower cover 7 and the one side plate 5a and the plate member 12 of sheet metal which has a through hole 12a, through which the RF connector 4 passes, and covers the one side plate 5a. The case member 11 includes connecting pieces 11a which are provided in a protruding manner at two positions on a longitudinal one end side (the plate member 12 side), slits 11b which are provided at two positions on the other side and protruding pieces for regulation 11c which are formed near to a top edge and a bottom edge of a base end portion of each of the connecting pieces 11a. Further, a lower end of the case member 11 is provided with the inwardly bent flat portions 11d which are formed at multiple positions and a plurality of leg pieces 11e which are vertically suspended. On the other hand, the plate member 12 is provided with the slits 12b which are bored at two positions corresponding to the attaching pieces 5b on one end side in a longitudinal direction of the frame body 5 and the slits 12c which are bored at two positions corresponding to the connecting pieces 11a of the case member 11. As will be described as follows, although the attaching pieces 5b protruding to the RF connector 4 side are caulk-fixed in a state of being inserted into the slits 12b, the protruding pieces 5c for regulation are adapted to be inserted into the slits 12b so as to be able to engage therewith. Similarly, although the connecting pieces 11a are caulk-fixed in a state of being inserted into the slits 12c, the protruding pieces 11c for regulation are adapted to be inserted into the slits 12c so as to be able to engage therewith. Further, the lower end of the plate member 12 is provided with the inwardly bent flat portions 12d which are formed at multiple positions and a plurality of leg pieces 12e which are vertically suspended.

When assembling the outer case 10, first, the plate member 12 is superimposed on the one side plate 5a of the shield case 3 by inserting the RF connector 4 of the tuner unit 1 into the through hole 12a of the plate member 12 and inserting the attaching pieces 5b on one end side in a longitudinal direction of the frame body 5 into the slits 12b. At this time, since the protruding pieces 5c for regulation provided near to a top edge and a bottom edge of the base end portion of the attaching piece 5b are respectively inserted into the upper end and the lower end of the slits 12b to be able to engage therewith, it is possible to attach the plate member 12 to the shield case 3 with high positioning accuracy. Subsequently, although the caulk-fixing to the plate member 12 is performed by twisting the attaching pieces 5b (See FIG. 1), at the time of the attachment by caulking, since the protruding pieces 5c for regulation are regulated in position by being engaged with both the upper and lower ends of the slits 12b, there is no possibility that the shield case 3 will be undesirably deformed.

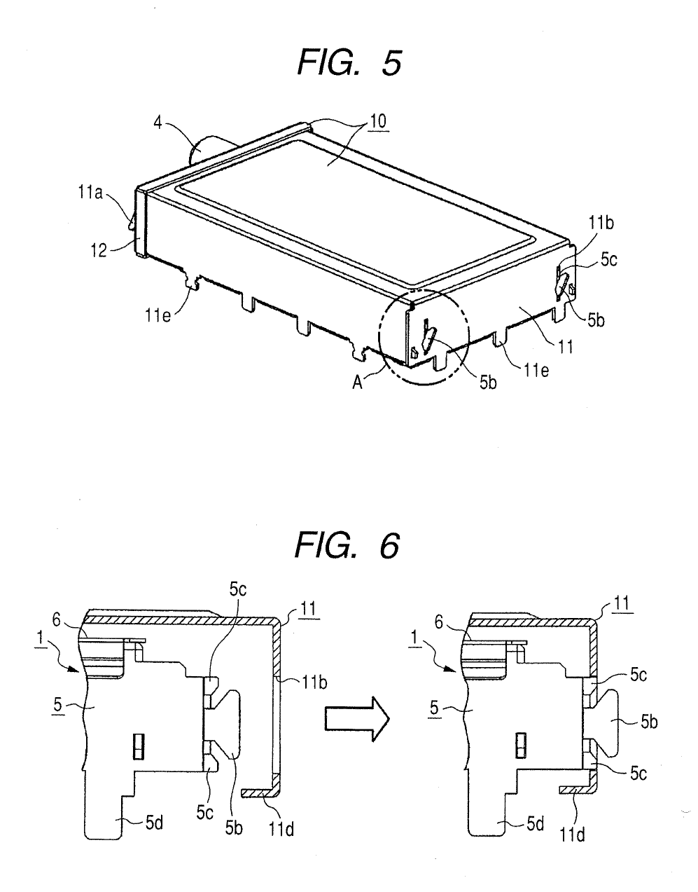

After the plate member 12 is attached to the shield case 3 as described above, the case member 11 fits over the shield case 3 from a side opposite to the plate member 12, the connecting pieces 11a are inserted into the slits 12c of the plate member 12, and the attaching pieces 5b on the other end side in a longitudinal direction of the frame body 5 are inserted into the slits 11b. At this time, since the protruding pieces 11c for regulation provided near to the connecting pieces 11a are inserted into the upper end and the lower end of the slits 12c to be able to engage therewith, it is possible to connect the case member 11 to the plate member 12 with high positioning accuracy. Further, since the protruding pieces 5c for regulation provided near to the attaching pieces 5b on the other end side in a longitudinal direction of the frame body 5 are, as shown in FIG. 6, inserted into the upper end and the lower end of the slits 11b to be able to engage therewith, it is possible to connect the case member 11 to the shield case 3 with high positioning accuracy. Subsequently, by twisting the connecting pieces 11a to perform a caulk-fixing to the plate member 12 (refer to FIG. 1) and by twisting the attaching pieces 5b to perform a caulk-fixing to the one side plate of the case member 11 (refer to FIG. 5), the outer case 10 is adapted to be unitized with the shield case 3 as a mantle body. Further, at a time of caulking the connecting pieces 11a, since the protruding pieces 11c for regulation are regulated in position by being engaged with both the upper and lower ends of the slits 12c, there is no possibility that the case member 11 will be undesirably deformed. Similarly, at a timing of caulking the attaching pieces 5b, since the protruding pieces 5c for regulation are regulated in position by being engaged with both the upper and lower ends of the slits 11b, there is no possibility that the shield case 3 will be undesirably deformed.

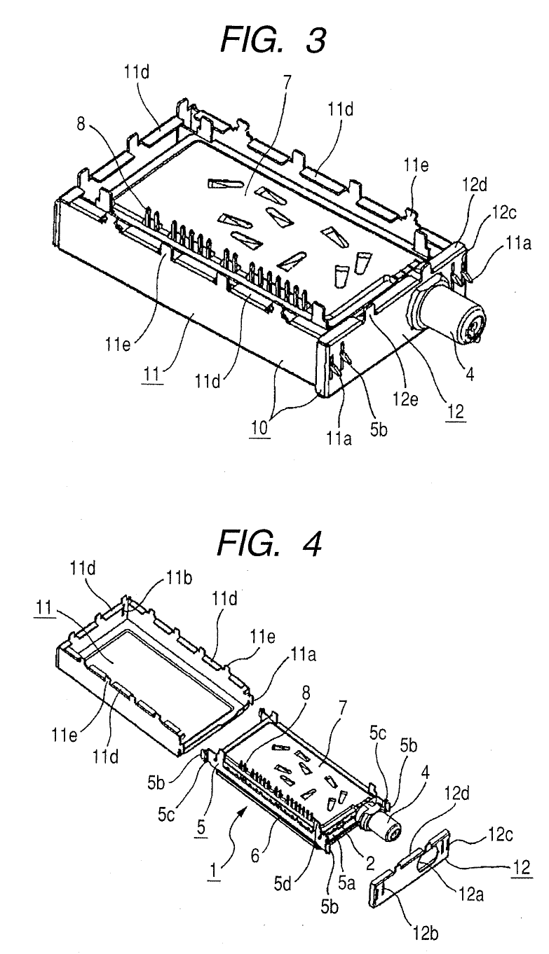

Finally, by caulk-fixing a peripheral portion of the through hole 12a of the frame member 12 to the RF connector 4 and solder-bonding the peripheral portion of the through hole 12a to the RF connector 4, the clearance between the peripheral portion of the through hole 12a and the connector 4 is completely blocked. In this way, as the outer case 10 (the case member 11 and the plate member 12) is attached to the tuner unit 1, the tuner apparatus shown in FIGS. 1 and 3 is completed.

Then, when mounting the tuner apparatus to the motherboard (not shown), each of the attaching legs 5d of the shield case 3 (frame body 5) and each of the leg pieces 11e and 12e of the outer case 10 is respectively inserted and fixed to the corresponding insertion holes on the motherboard side so as to be fixed, and each of the terminals 8 of the tuner unit 1 is connected to the outer circuit on the motherboard side. Therefore, it is possible to easily and reliably attach the previously unitized shield case 3 and the outer case 10 to the motherboard, and to mount each of the flat portions 11d and 12d of the outer case 10 to a predetermined area of the top surface of the motherboard. For this reason, if the ground pattern on the motherboard side is disposed at the mounting area, it is possible to reinforce the ground of the tuner apparatus. Thus, in the tuner apparatus mounted on the motherboard, since the frame body 5 of the shield case 3 having notches or holes formed at multiple positions is completely covered by the outer case 10, a shielding effect to prevent diving or jumping of the electromagnetic noise is extremely high.

As described above, in the tuner apparatus according to the present embodiment, the plate member 12 in which the RF connector 4 is inserted into the through hole 12a is superimposed on the one side plate 5a of the frame body 5 so that it can be easily attached to the shield case 3, and the case member 11 which is fitted over the shield case 3 from a side opposite to the plate member 12 is easily connected to the plate member 12 so that a box-shaped outer case 10 can be formed. Accordingly, it is possible to simply perform a connecting operation of the outer case 10 and an attaching operation to the shield case 3. That is, when connecting the case member 11 and the plate member 12, since connection of the case member 11 and the plate member 12 is made effective by just inserting the connecting pieces 11a into the slits 12c while regulating their positions by the protruding pieces 11c for regulation and twisting them, workability is excellent and positional deviation or undesirable deformation can be effectively prevented. Similarly, when attaching the case member 11 and the plate member 12 to the shield case 3, since this attaching is made effective by just inserting the attaching pieces 5b into the slits 11b and slits 12b while regulating their positions by the protruding pieces 5c for regulation and twisting them, workability is excellent and positional deviation or undesirable deformation can be effectively prevented. For this reason, in the tuner apparatus including such an outer case 10, it is possible to realize a shield structure having extremely high shielding effect and excellent reliability at a low cost.

In addition, in the tuner apparatus according to the present embodiment, since the RF connector 4 provided at the tuner unit 1 to protrude sideways is caulk-fixed and solder-bonded to the peripheral portion of the through hole 12a of the plate member 12, the clearance between the peripheral portion of the through hole 12a and the RF connector 4 comes to a completely blocked state, and thus a shielding effect becomes higher and an attaching strength of the RF connector 4 becomes higher.

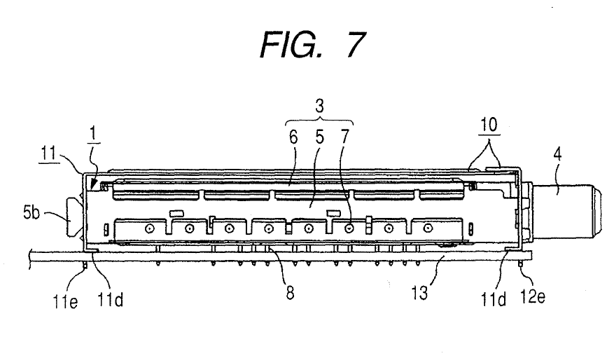

Further, although a case in which each of the attaching legs 5d of the shield case 3 (frame body 5) and each of the leg pieces 11e and 12e of the outer case 10 is respectively inserted and fixed to the corresponding insertion holes on the motherboard side so as to be fixed is described in the tuner apparatus according to the present embodiment, as shown in FIG. 7, by removing the attaching legs of the shield case 3, it may be possible to attach a unitized product of the shield case 3 and the outer case 10 to the motherboard 13 only by each of the leg pieces 11e and 12e on the outer case 10 side. If so, since an exogenous disturbing signal does not break into the tuner circuit via the attaching legs on the shield case 3, it is possible to suppress deterioration of the exogenous signal disturbance (immunity).

It should be understood by those skilled in the art that various modifications, combinations, sub-combinations and alterations may occur depending on design requirements and other factors insofar as they are within the scope of the appended claims or the equivalents thereof.

What is claimed is:

1. A shield structure of a tuner apparatus, comprising:
a circuit board on which a tuner circuit is provided;
a shield case of sheet metal which accommodates and holds the circuit board; and
a RF connector which is fixed to one side plate of the shield case so as to protrude outward and is electrically connected to the tuner circuit,
wherein a box-shaped outer case includes a case member of sheet metal, which covers the shield case with the exception of the bottom surface portion thereof connected with the one side plate and a plate member of sheet metal which has a through hole, through which the RF connector passes, and covers the one side plate of the shield case, and
wherein the outer case is unitized with the shield case.

2. The shield structure according to claim 1,
wherein the shield case includes attaching pieces which protrude at both ends in a longitudinal direction of a side plate adjacent to the one side plate,
wherein the attaching pieces on one side are inserted through and caulked to first slits provided on the plate member so that the plate member and the shield case are unitized, and
wherein the attaching pieces on the other side are inserted through and caulked to second slits provided on the case member so that the case member and the shield case are unitized.

3. The shield structure according to claim 2,
wherein the shield case includes the protruding pieces for regulation which are respectively formed near to a top edge and a bottom edge of a base end portion of each of the attaching pieces, and these protruding pieces for regulation are inserted into both the upper and lower ends of the first or second slits so as to be able to engage therewith.

4. The shield structure according to claim 1,
wherein the case member includes connecting pieces which protrude at one end in a longitudinal direction of a side plate disposed adjacent to the plate member, and
wherein the connecting pieces are inserted through and caulked to third slits provided on the plate member so that the plate member and the case member are connected to each other.

5. The shield structure according to claim 4,
wherein the case member includes the protruding pieces for regulation which are respectively formed near to a top edge and a bottom edge of a base end portion of each of the connecting pieces, and these protruding pieces for regulation are inserted into both the upper and lower ends of the third slits so as to be able to engage therewith.

6. The shield structure according to claim 1,
wherein a plurality of leg pieces are vertically suspended from a bottom end of the outer case, and the leg pieces are fixed to a motherboard.

7. The shield structure according to claim 6,
wherein a unitized product of the shield case and the outer case is fixed to the motherboard only by the leg pieces of the outer case.

8. The shield structure according to claim 1,
wherein the inwardly bent flat portions are formed at a lower end of the outer case, and the flat portions are mounted onto a ground pattern on the motherboard side.

9. The shield structure according to claim 1,
wherein a peripheral portion of the through hole of the plate member is caulk-fixed to the RF connector, and the peripheral portion of the through hole and the RF connector are solder-bonded to each other.
